(19) United States
(12) Patent Application Publication
(10) Pub. No.: US 2025/0204095 A1
(43) Pub. Date: Jun. 19, 2025

(54) LIGHT EMITTING ELEMENT

(71) Applicant: NICHIA CORPORATION, Anan-shi (JP)

(72) Inventors: Takumi OTSUKA, Anan-shi (JP); Eiji MURAMOTO, Tokushima-shi (JP)

(73) Assignee: NICHIA CORPORATION, Anan-shi (JP)

(21) Appl. No.: 18/975,628

(22) Filed: Dec. 10, 2024

(30) Foreign Application Priority Data
Dec. 14, 2023 (JP) 2023-211178

(51) Int. Cl. H01L 33/38; H01L 33/32

(52) U.S. Cl. CPC H10H 20/831; H10H 20/825

(57) ABSTRACT

A light emitting element comprises a semiconductor structure that includes an n-side layer, a p-side layer, and an ultraviolet light emitting active layer interposed between these layers; an n-side electrode electrically connected to the n-side layer; and a p-side electrode electrically connected to the p-side layer. The n-side layer has an undoped first layer and a second layer positioned between the active layer and the first layer and containing an n-type impurity. The n-side electrode includes a first electrode and a second electrode that are in contact with the second layer, but not in contact with the first layer. The reflectance of the first electrode for a peak wavelength of light emitted from the active layer is higher than the reflectance of the second electrode for the peak wavelength of the light emitted from the active layer.

### CROSS REFERENCE TO RELATED APPLICATIONS

The present application claims priority under 35 U.S.C. § 119 to Japanese Patent Application No. 2023-211178, filed Dec. 14, 2023, the contents of which is hereby incorporated by reference in its entirety.

### BACKGROUND

### 1. Technical Field

The present disclosure relates to a light emitting element.

### 2. Description of Related Art

As an ultraviolet light emitting element, for example, Japanese Patent Publication No. 2017-028032 discloses a group III nitride semiconductor light emitting element emitting light having a peak wavelength in a range of 200 to 350 nm.

### SUMMARY

An object of the present disclosure is to provide a light emitting element that can reduce the absorption of ultraviolet light by the electrodes while ensuring the conduction between the electrodes and the semiconductors to thereby increase the emission efficiency.

A light emitting element according to one embodiment of the present disclosure comprises: a semiconductor structure that includes an n-side layer, a p-side layer, and an ultraviolet light emitting active layer disposed between the n-side layer and the p-side layer, each made of a nitride semiconductor; an n-side electrode electrically connected to the n-side layer; and a p-side electrode electrically connected to the p-side layer. The n-side layer has an undoped first layer and a second layer positioned between the active layer and the first layer and containing an n-type impurity. The n-side electrode includes a first electrode and a second electrode that are in contact with the second layer, and not in contact with the first layer. The reflectance of the first electrode for the peak wavelength of the light from the active layer is higher than the reflectance of the second electrode for the peak wavelength of the light from the active layer. The contact resistance between the second electrode and the second layer is lower than the contact resistance between the first electrode and the second layer.

A light emitting element according to certain embodiments of the present disclosure can reduce the absorption of ultraviolet light by the electrodes while ensuring the conduction between the electrodes and the semiconductors thereby increasing the emission efficiency.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a plan view of a light emitting element according to Embodiment 1 of the present disclosure.

FIG. 2 is a cross-sectional view of the light emitting element according to Embodiment 1 of the present disclosure taken along line II-II in FIG. 1.

FIG. 3 is a plan view of a semiconductor structure constituting the light emitting element according to Embodiment 1 of the present disclosure.

FIG. 4 is a plan view showing the n-side electrode and the p-side electrode included in the light emitting element according to Embodiment 1 of the present disclosure.

FIG. 5 is a cross-sectional view of the light emitting element according to Embodiment 1 of the present disclosure taken along line I-I in FIG. 1.

FIG. 6 is a plan view showing the n-side electrode and the p-side electrode included in a light emitting element according to Embodiment 2 of the present disclosure.

FIG. 7 is a cross-sectional view of the light emitting element according to Embodiment 2 of the present disclosure taken along line I-I in FIG. 6.

FIG. 8 is a cross-sectional view of the light emitting element according to Embodiment 2 of the present disclosure taken along line II-II in FIG. 6.

FIG. 9 is a plan view showing the n-side electrode and the p-side electrode included in a light emitting element according to Embodiment 3 of the present disclosure.

FIG. 10 is a cross-sectional view of the light emitting element according to Embodiment 3 of the present disclosure taken along line I-I in FIG. 9.

FIG. 11 is a cross-sectional view of the light emitting element according to Embodiment 3 of the present disclosure taken along line II-II in FIG. 9.

FIG. 12 is a plan view of a semiconductor structure constituting an example of a light emitting element according to Embodiment 4 of the present disclosure.

FIG. 13 is a cross-sectional view showing the n-side electrode included in the example of a light emitting element according to Embodiment 4 of the present disclosure.

FIG. 14 is a plan view of a semiconductor structure constituting another example of a light emitting element according to Embodiment 4 of the present disclosure.

FIG. 15 is a plan view of a semiconductor structure constituting an example of a light emitting element according to Embodiment 5 of the present disclosure.

FIG. 16 is a cross-sectional view showing the n-side electrode provided in the example of a light emitting element according to Embodiment 5 of the present disclosure.

FIG. 17 is a plan view of a semiconductor structure constituting another example of a light emitting element according to Embodiment 5 of the present disclosure.

FIG. 18 is a plan view of a light emitting element according to Embodiment 6 of the present disclosure.

FIG. 19 is a cross-sectional view of the light emitting element according to Embodiment 6 of the present disclosure taken along line II-II in FIG. 18.

FIG. 20 is a plan view of the n-side conducting part included in the light emitting element according to Embodiment 6 of the present disclosure.

FIG. 21 is a plan view of the n-side wiring part included in the light emitting element according to Embodiment 6 of the present disclosure.

FIG. 22 is a graph showing the light output rate of each light emitting element in Examples 1 to 6 as compared to the light output of the light emitting element in Comparative Example 1.

### DETAILED DESCRIPTION

### Embodiment 1

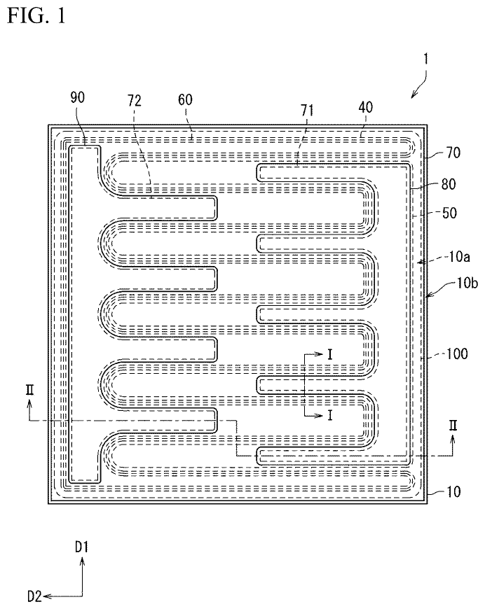

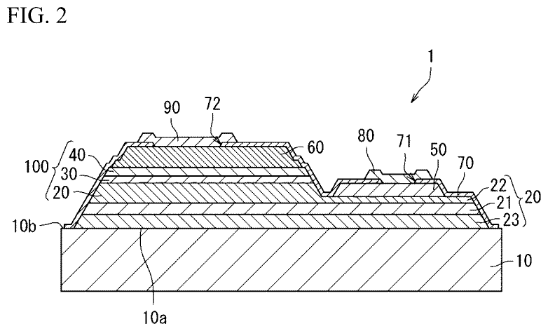

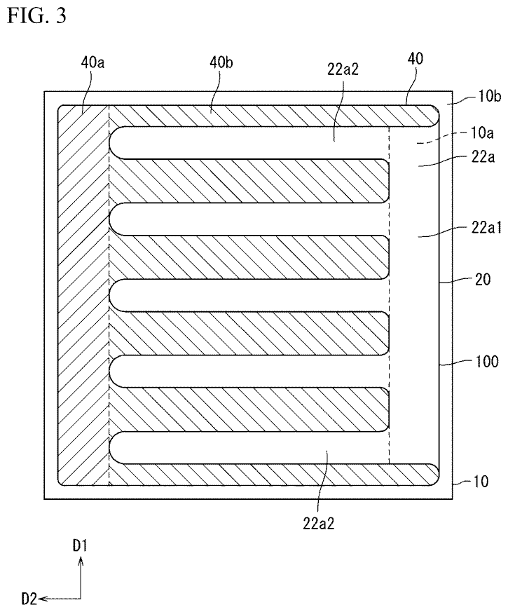

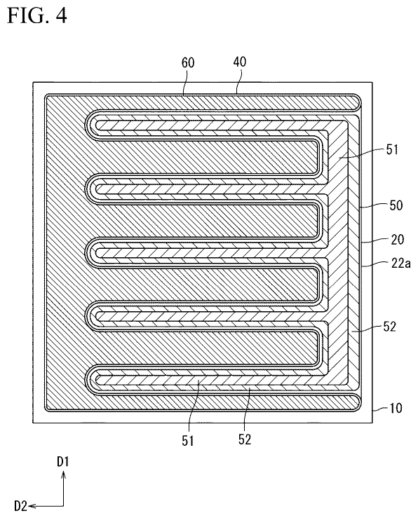

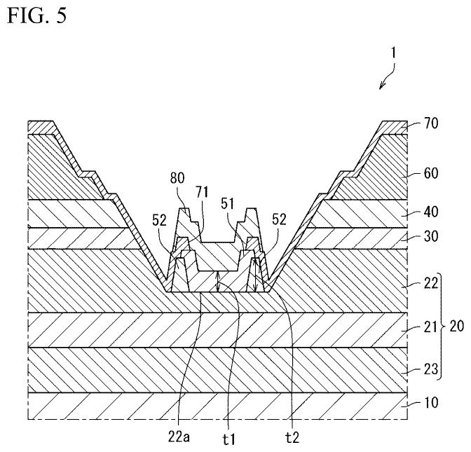

FIG. 1 and FIG. 2, which are respectively plan and cross-sectional views, show a light emitting element according to Embodiment 1 of the present disclosure. FIG. 1 is a plan view of the light emitting element 1 of this embodiment. FIG. 3 is a plan view schematically showing the layout of the n-side layer and the p-side layer that constitute the light emitting element 1. FIG. 4 is a plan view schematically showing the layout of the n-side electrode 50 and the p-side electrode 60, in which the regions marked with hatching show the regions where members or parts are disposed, not representing a cross section. FIG. 5 is a cross-sectional view schematically showing a portion of the light emitting element 1, the n-side electrode 50 in FIG. 1, taken along line I-I in FIG. 1. FIG. 2 is a cross-sectional view schematically showing the light emitting element 1 taken along line II-II in FIG. 1.

As shown in these drawings, the light emitting element 1 in this embodiment has a substrate 10 and a semiconductor structure 100 disposed on the substrate 10. As shown in FIG. 2 and FIG. 5, the semiconductor structure 100 has an n-side layer 20, a p-side layer 40, and an ultraviolet light emitting active layer 30 interposed between the n-side layer 20 and the p-side layer 40, each made of a nitride semiconductor. The n-side layer 20 has an undoped first layer 21 and a second layer 22 interposed between the active layer and the first layer 21 and containing an n-type impurity. The light emitting element 1 includes an n-side electrode 50 electrically connected to the n-side layer 20 and a p-side electrode 60 electrically connected to the p-side layer 40. The light emitting element 1 further has an insulation layer 70, an n-side pad electrode 80, and a p-side pad electrode 90. The n-side pad electrode 80 is electrically connected to the n-side electrode 50 at a first opening 71 provided in the insulation layer 70, and the p-side pad electrode 90 is electrically connected to the p-side electrode 60 at a second opening 72 provided in the insulation layer 70. The semiconductor structure 100 is formed on the substrate 10. In Embodiment 1, the ultraviolet light emitted by the active layer 30 is primarily extracted from the substrate 10 side.

As shown in FIG. 4 and FIG. 5, the n-side electrode 50 includes a first electrode 51 and a second electrode 52. The first electrode 51 and the second electrode 52 are both in contact with the second layer 22, and not in contact with the first layer 21. The reflectance of the first electrode 51 for the peak wavelength of the light from the active layer 30 is higher than the reflectance of the second electrode 52 for the peak wavelength of the light from the active layer 30. The contact resistance between the second electrode 52 and the second layer 22 is lower than the contact resistance between the first electrode 51 and the second layer 22.

A metal having a high reflectance for ultraviolet light tends to increase the contact resistance with the n-side layer 20. Moreover, subjecting the n-side layer 20 and a metal disposed on the n-side layer 20 to annealing for the purpose of reducing the contact resistance tends to reduce the reflectance of the metal disposed on the n-side layer 20. On the other hand, a metal having a low reflectance for ultraviolet light tends to lower the contact resistance with the n-side layer 20. In this embodiment, as an electric current flows through the light emitting element 1, the first electrode 51 reflects the light from the active layer 30 while playing the role of moving electrons, and the second electrode 52 plays the role of supplying electrons to the n-side layer 20. Accordingly, with the n-side electrode 50 provided in a relatively large area for electric current distribution purposes as shown in FIG. 1, this embodiment can distribute the current to reduce emission nonuniformity, while reducing the ultraviolet light absorption by the n-side electrode 50, thereby improving the emission efficiency.

In this embodiment, as shown in FIG. 5, the first electrode 51 and the second electrode 52 are both in contact with the second layer 22 that contains an n-type impurity, but not in contact with the first layer 21. In other words, in the exposed region 22a of the n-side layer 20 on which the n-side electrode 50 is disposed, the first layer 21 is not exposed from the second layer 22. Because the contact resistance of the undoped first layer 21 with a metal tends to become high, allowing the first electrode 51 and the second electrode 52 to be in contact with the second layer 22 that contains an n-type impurity, and not allowing them to be in contact with the undoped first layer 21, can lessen the forward voltage Vf increase. In the n-side layer 20, moreover, the undoped first layer 21 is a part having high electrical resistance which does not readily function as a current path, whereas the second layer 22 that contains an n-type impurity is a part having low electrical resistance which can readily function as a current path. In this embodiment, not allowing the first layer 21 to be exposed in the exposed region 22a of the n-side layer 20 where the n-side electrode 50 is disposed can reduce the current nonuniformity in the n-side layer 20. This, as a result, can reduce light emission nonuniformity in the light emitting element 1.

Here, an undoped layer is a layer not intentionally doped with an n-type impurity or a p-type impurity. In the case in which an undoped layer is adjacent to a layer intentionally doped with an n-type impurity and/or a p-type impurity, the undoped layer might contain the n-type impurity and/or the p-type impurity diffused from the adjacent layer. Even when the undoped first layer 21 contains an n-type impurity, the impurity concentration is lower than 1×10¹⁷/cm³. The n-type impurity concentration in the second layer 22 is, for example, in a range of 5×10¹⁸/cm³ to 1×10²⁰/cm³.

This embodiment will be explained in more detail below.

### Substrate

For the material for the substrate 10, for example, sapphire, silicon (Si), gallium nitride (GaN), aluminum nitride (AlN), or the like can be used. A substrate 10 made of sapphire is preferable, as it has a high transmittance with respect to the ultraviolet light from the active layer 30. The semiconductor structure 100 can be disposed, for example, on C-plane of the sapphire substrate, and is preferably disposed on a face oblique to the C-plane of the sapphire substrate forming a 0.2 to 2 degree angle with the a-axis or the m-axis of the sapphire substrate. The thickness of the substrate 10 can be set, for example, in a range of 150 μm to 800 μm. The light emitting element 1 does not have to have a substrate 10.

A plan view shape of the substrate 10 is, for example, quadrangular. In the case in which the plan view shape of the substrate 10 is quadrangular, each side can be set in a range of about 500 μm to about 2000 μm in length. The upper face of the substrate 10 has a first substrate region 10a where a semiconductor structure 100 is disposed and a second substrate region 10b where no semiconductor structure 100 is disposed. When viewed from above, the first substrate region 10a is surrounded by the second substrate region 10b. The boundary between the first substrate region 10a and the second substrate region 10b is located 10 μm to 30 μm from the outline of the substrate 10, for example. Here, as shown in FIG. 1, a direction parallel to one side of the substrate is denoted as a first direction D1, and the direction orthogonal to the first direction D1 is denoted as the second direction D2.

### Semiconductor Structure

A semiconductor structure 100 is a stack structure in which nitride semiconductor layers are stacked. The nitride semiconductor can be any semiconductor obtained by varying the composition ratio x and y within their ranges in the chemical formula InₓAl_{y}Ga_{1-x-y}N (0≤x≤1, 0≤y≤1, x+y≤1).

The semiconductor structure 100 has an n-side layer 20, an active layer 30, and a p-side layer 40. The active layer 30 is disposed between the n-side layer 20 and the p-side layer 40.

An n-side layer 20 includes one or more n-type semiconductor layers, and includes, as described above, an undoped first layer 21 and a second layer containing an n-type impurity. Examples of n-type impurities include silicon (Si), germanium (Ge), and the like. An n-type semiconductor layer is, for example, an AlGaN layer containing aluminum (Al), gallium (Ga), and nitrogen (N), and may contain indium (In).

An n-side layer 20 can include, for example, a third layer 23 as a superlattice layer, an undoped first layer 21 as an underlayer, and a second layer 22 containing an n-type impurity as an n-contact layer successively from the substrate 10 side.

The third layer 23 has a multilayer structure in which semiconductor layers A and semiconductor layers B having a different lattice constant from that of the semiconductor layers A are alternately stacked. The third layer 23 has the function of reducing the stress occurring in the semiconductor layers disposed above the third layer 23. The third layer 23 can be a multilayer structure in which AlN layers and aluminum gallium nitride (AlGaN) layers are alternately stacked, for example. The number of pairs of the first and second semiconductor layers in the third layer 23 can be set in a range of 20 to 50 pairs. The total thickness of the third layer 23 can be set, for example, in a range of 300 nm to 3000 nm, particularly 600 nm to 1600 nm. The third layer 23 can be an undoped layer.

For the first layer 21, for example, an undoped AlGaN layer can be used. In the case of using an AlGaN layer for the first layer 21 as an underlayer, the Al composition ratio of the AlGaN layer can be set, for example, in a range of 50% or higher. The thickness of the first layer 21 may be set, for example, in a range of 200 nm to 1000 nm, particularly 400 nm to 600 nm.

For the second layer 22, for example, an AlGaN layer containing an n-type impurity can be used. In the case of using an AlGaN layer for the second layer 22 as an n-contact layer, the Al composition ratio of the AlGaN layer can be set, for example, in a range of 50% or higher. In the present specification, an AlGaN layer having an Al composition ratio of 50%, for example, means that the composition ratio x in the chemical formula Al_{X}Ga_{1-X}N is 0.5. The n-type impurity concentration of the second layer 22 can be set, for example, in a range of 5×10¹⁸/cm³ to 1×10²⁰/cm³. The thickness of the second layer 22 may be set, for example, in a range of 1000 nm to 3000 nm, particularly 1500 nm to 2500 nm.

As shown in FIG. 3, the second layer 22 which is an n-contact layer has an exposed region 22a exposed from the p-side layer 40 and the active layer 30, and an n-electrode 50 is disposed on a portion of the exposed region 22a as shown in FIG. 4. Here, x being exposed from y refers to a situation in which s portion of x is covered by y and another portion of x is not covered by y, while permitting the portion not covered by y to be covered by another element or member.

The exposed region 22a, as shown in the plan view in FIG. 3, has a first region 22a1 extending in the first direction D1 and a second region 22a2 extending from the first region 22a1 in the second direction D2 which is orthogonal to the first direction D1 and is positioned between sections of the p-side layer 40 in the first direction D1. There are multiple second regions 22a2. In the case in which multiple second regions 22a2 are provided, the second regions 22a2 are preferably arranged substantially at equal intervals in the first direction D1. This layout can reduce current density distribution variations. Here, “substantially at equal intervals” tolerates deviations of up to 1 μm.

In FIG. 3, the region located on the periphery of the substrate 10 denoted by the reference numeral 10b is a second substrate region where the substrate 10 is exposed from the semiconductor structure 100. Neither the n-side electrode 50 nor the p-side electrode 60 is disposed in the second substrate region 10b. The width of the first substrate region 10a may be, for example, 940 μm to 970 μm.

The first region 22a1 and the second regions 22a2 may have the shapes described below, for example.

The length of the first region 22a1 in the first direction D1: 70% to 85% of the length of the substrate in the first direction D1.

The length of the first region 22a1 in the second direction D2: 5% to 20% of the length of the substrate in the second direction D2.

The number of second regions 22a2: 3 to 6.

The length of a second region 22a2 in the first direction D1: 5% to 20% of the length of the substrate in the first direction D1.

The length of a second region 22a2 in the second direction D2: 70% to 85% of the length of the substrate in the second direction D2.

The spacing of the second regions 22a2 in the first direction (distance between the center lines extending in the second direction D2 of two adjacent second regions): 5% to 20% of the length of the substrate in the first direction D1.

The p-side layer 40 includes one or more p-type semiconductor layers. Examples of p-type semiconductor layers include those that contain a p-type impurity such as magnesium (Mg), or the like. The p-side layer may include multiple layers each having a different p-type impurity concentration and/or Al composition ratio. The p-type impurity concentration is, for example, 1×10¹⁹/cm³ to 1×10²¹/cm³.

In the case in which the p-side layer 40 includes three p-type semiconductor layers, a lower layer having an Al composition ratio of 60% to 70%, a middle layer having an Al composition ratio of 30% to 60%, and an upper layer having an Al composition ratio of 3% or lower may be disposed successively from the substrate 10 side. In the case in which the p-side layer 40 has these three layers, a portion of the upper layer may be removed to expose the middle layer to dispose the p-side electrode 60 in contact with the upper layer and the exposed region of the middle layer. This layout allows the interface between the p-side electrode and the middle layer to efficiently reflect the light from the active layer 30 while reducing the absorption of the light from the active layer 30 by the upper layer that has a high Al composition ratio to readily absorb ultraviolet light. Moreover, disposing the p-side electrode 60 in contact with not only the middle layer, but also the upper layer can reduce the contact resistance between the p-side electrode 60 and the p-side layer 40, as compared to the case in which the electrode is in contact only with the middle layer. Furthermore, disposing the p-side electrode 60 in contact with the surface of the middle layer and the surface of the upper layer can improve the adhesion between the p-side electrode 60 and the p-side layer 40 as compared to the case in which the p-side electrode 60 is in contact only with the surface of the upper layer.

In the case in which the p-side layer 40 includes the three p-type semiconductor layers described above, the thickness of the lower layer is preferably set larger than the thicknesses of the middle and upper layers. The thickness of the lower layer may be set, for example, in a range of 20 nm to 40 nm. The thickness of the middle layer may be set, for example, in a range of 3 nm to 20 nm, particularly 3 nm to 15 nm. The thickness of the upper layer may be set, for example, in a range of 3 nm to 20 nm, particularly 3 nm to 15 nm. The p-side layer 40 may further include another layer between the lower layer and the active layer 30.

The p-side layer 40, as shown in FIG. 3, has a base 40a extending in the first direction D1 and multiple extended portions 40b extending in the second direction D2. In the plan view, all of the sides of the second regions 22a2 that are parallel to the second direction D2 are opposing the extended portions 40b. This layout allows all of the sides of the second regions 22a2 that are parallel to the second direction D2 to oppose the p-side layer 40. The extended portions 40b positioned at both ends in the first direction D1 are longer in the second direction D2 than the other extended portions 40b so as to oppose the ends of the first region 22a1 in the first direction D1.

The length of the base 40a of the p-side layer 40 in the second direction D2 is determined by the lengths of the first region 22a1 and the second regions 22a2, for example. The lengths of the extended portions 40b in the first direction D1 are determined by the lengths of the second regions 22a2 in the first direction D1 and the spacing. The lengths of the extended portions 40b excluding the two positioned at the ends in the first direction D1 in the second direction D2 are determined by the lengths of the second regions 22a2 in the second direction D2, and have substantially the same lengths as the lengths of the second regions 22a2 in the second direction D2.

The active layer 30 has a well layer containing Al and a barrier layer containing Al. The active layer 30 has, for example, a multiple quantum well structure including multiple well layers and multiple barrier layers. The Al composition ratio of a barrier layer is higher than the Al composition ratio of a well layer. In other words, the band gap energy of a barrier layer is larger than the band gap energy of a well layer. From a well layer containing Al, light having an emission wavelength corresponding to the band gap energy is emitted. The structure of the active layer 30 is not limited to a multiple quantum well structure that includes multiple well layers, and may be a single quantum well structure. An n-type impurity and/or p-type impurity may be contained in at least some of the well layers and the barrier layers.

The well layer may be, for example, a layer made of AlGaN. The Al composition ratio of a well layer can be set, for example, in a range of 30% to 50%. In the case in which the well layer is configured to emit light having a peak emission wavelength of about 280 nm, for example, an AlGaN layer having an Al composition ratio of about 42% can be used for the well layer. The peak wavelength of the ultraviolet light emitted by a well layer may be in the range of 100 nm to 280 nm (C band), 280 nm to 315 nm (B band), or 315 nm to 405 nm (A band). The barrier layer may be, for example, a layer made of AlGaN. The Al composition ratio of a barrier layer can be set, for example, in a range of 30% to 60%.

The thickness of a well layer may be set, for example, in a range of 3 nm to 6 nm. The thickness of a barrier layer is, for example, in a range of 2 nm to 4 nm.

The active layer 30 together with the p-side layer 40 exposes the second layer 22 that is the second layer of the n-side layer 20. Accordingly, the plan view shape and dimensions of the active layer 30 are substantially the same as those of the p-side layer 40.

A buffer layer (not shown) may be disposed between the substrate 10 and the semiconductor structure 100. For the buffer layer, for example, an AlN layer can be used. The buffer layer functions to reduce lattice mismatch between the substrate 10 and the nitride semiconductor layers disposed on the buffer layer. The thickness of the buffer layer can be set, for example, in a range of 1.5 μm to 4 μm.

### N-Side Electrode

An n-side electrode 50 is disposed in the exposed region 22a, and has a first electrode 51 and a second electrode 52. As shown in FIG. 4, the first electrode 51 has a similar shape to that of the exposed region 22a in the plan view. As shown in FIG. 5, in the cross-sectional view, the first electrode 51 is positioned between sections of the second electrode 52 where two lateral faces of the first electrode 51 are in contact with the second electrode 52 at least in part, and the bottom face of the first electrode 51 and the bottom face of the second electrode 52 are both in contact only with the second layer 22. This layout can shorten the current path between the second electrode 52 and the p-side electrode 60, thereby lessening the Vf increase.

The reflectance of the first electrode 51 for the peak wavelength of the light emitted by the active layer 30 is higher than the reflectance of the second electrode 52 for the peak wavelength of the light emitted by the active layer 30. The contact resistance between the second electrode 52 and the exposed region 22a (i.e., the second layer 22) is lower than the contact resistance between the first electrode 51 and the second region 22a2.

The first electrode 51 may be made of a material containing at least one metal selected from Au, Ag, Al, Ni, Pd, Ge, Si, Sn, Ti, Rh, Pt, Mo, Ta, Ru, and W, and, for example, can be made of an alloy having one or more of these metals as components. The first electrode 51 is preferably configured such that the face in contact with the second layer 22 has a reflectance of 60% or higher, particularly 85% or higher for the peak wavelength of the ultraviolet light from the active layer 30. Examples of metals that have a high reflectance for ultraviolet light include Al, Mg, and Ru. The face of the first electrode 51 that is in contact with the second layer 22 preferably includes at least one of these metals. In the case in which the face of the first electrode 51 in contact with the second layer 22 is made of an alloy of Al and another metal, for example, the percentage of Al is preferably 70 atomic percent or higher. The metal to form the alloy with Al may be, for example, Si, Cu, or Ti. The first electrode 51 may have a multilayer structure having multiple layers. The first electrode 51 having a multilayer structure may have an Al—Cu alloy layer, a Ti layer, and a Ru layer successively stacked from the second layer 22 side.

The second electrode 52 may be made of a material containing at least one metal selected from Au, Ag, Al, Ni, Pd, Ge, Si, Sn, Ti, Rh, Pt, Mo, Ta, Ru, and W, and, for example, can be made of an alloy having one or more of these metals as components. The second electrode 52 might occasionally be subjected to annealing for improving the ohmic contact with the n-side layer 20, and the reflectance of the metal subsequent to annealing generally is lower than the reflectance before annealing. For this reason, even if the first electrode 51 and the second electrode 52 are made of the same metal, the relationships with respect to the reflectance and the contact resistance described above can occasionally be satisfied. The second electrode 52 may have a multilayer structure having multiple layers. The second electrode 52 having a multilayer structure may have a Ti—Al—Si alloy, a Ta layer, and a Ru layer stacked successively from the second layer 22 side.

The first electrode 51 functions as the path for carrying electrons supplied by the n-side pad electrode 80, and has a high reflectance for the ultraviolet light emitted by the active layer 30 to thereby increase the emission efficiency of the light emitting element 1. In this embodiment, the area of the second electrode 52 having a lower contact resistance with the second layer 22 that is in contact with the second layer 22 is relatively small as compared to the case in which the entire n-side electrode 50 is the second electrode 52. However, because the second electrode 52 is disposed to be in contact with the second layer 22 while covering the lateral faces of the first electrode 51 as shown in FIG. 5, it can supply electrons to the active layer 30 while reducing the current density distribution nonuniformity. This, combined with the ultraviolet light reflection by the first electrode 51, can increase the emission efficiency of the light emitting element 1 as a whole.

As shown in FIG. 5, in the case in which the first electrode 51 and the second electrode 52 are arranged side by side in contact with the exposed region 22a in the cross section, either one of the contact areas, i.e., one between the first electrode 51 and the exposed region 22a and one between the second electrode 52 and the exposed region 22a, may be larger. When the contact area between the first electrode 51 and the exposed region 22a is larger than the contact area between the second electrode 52 and the exposed region 22a, the effect of increasing the emission efficiency attributed to ultraviolet light reflection tends to be enhanced. When the contact area between the second electrode 52 and the exposed region 22a is larger than the contact area between the first electrode 51 and the exposed region 22a, the contact resistance between the entire n-side electrode 50 and the exposed region 22a (i.e., the second layer 22) tends to be reduced, which decreases the Vf.

In FIG. 4, the first electrode 51 is located over substantially the entire lengths of the second regions 22a2 in the second direction D2 and substantially the entire length of the first region 22a1 in the first direction D1. The first electrode 51 does not have to be located over substantially the entire lengths of the second regions 22a2 in the second direction D2. The first electrode 51 does not have to be located over substantially the entire length of the first region 22a1 in the first direction D1. The first electrode 51 may be located only in some of the second regions 22a2 instead of being located in each region.

Regardless of the layout of the first electrode 51, in a plan view, the total contact area between the first electrode 51 and the exposed region 22a in a plan view is preferably 35% to 70% of the contact area between the entire n-side electrode 50 and the exposed region 22a, and may particularly be 45% to 55%. When the percentage of the contact area between the first electrode 51 and the exposed region 22a is small, the effect of increasing emission efficiency attributed to ultraviolet light reflection tends to lessen. When the percentage is large, the percentage of the contact area between the second electrode 52 and the exposed region 22a decreases, which tends to increase the Vf.

In FIG. 5, the first electrode 51 is located in the recess defined by the lateral faces of the second electrode 52 and the upper face of the second layer 22. As shown in FIG. 5, the first electrode 51 may be in contact with the upper face of the second electrode 52. Arranging the first electrode 51 as described above can increase the adhesion to the second electrode 52. A portion of the first electrode 51 does not need to be in contact with the upper face of the second electrode.

The layout of the first electrode 51 and the second electrode 52 is not limited to that shown in FIG. 4 and FIG. 5. The layout of the first electrode 51 and the second electrode 52 may be, for example, the reversed layout of what is shown in FIG. 5. Specifically, the second electrode 52 may be placed in the recess defined by the lateral faces of the first electrode 51 and the upper face of the second layer 22. They may be arranged such that only one lateral face of the first electrode 51 is in contact with the second electrode 52, i.e., one side of the n-side electrode 50 is a lateral face of the first electrode 51 and the other side is a lateral face of the second electrode 52. However, the preferable layout is such that the outer edges of the first electrode 51 are surrounded by the outer edges of the second electrode 52. Surrounding the outer edges of the first electrode 51 with the second electrode 52 allows the p-side layer 40 and the p-side electrode 60 to oppose the second electrode 52 at the border between the p-side layer 40 and the n-side layer 20 in a plan view, which can facilitate the current flow between the n-side electrode 50 and the p-side electrode 60. This can reduce the current density distribution nonuniformity.

It is preferable for at least 70% of the outer edges of the n-side electrode 50 in a plan view to oppose the p-side layer 40. An n-side electrode 50 having such shape and layout can further facilitate the current flow between the n-side electrode 50 and the p-side electrode 60 thereby further reducing the current density distribution nonuniformity. The outer edges of the n-side electrode 50 that oppose the p-side layer 40 are more preferably the outer edges of the second electrode 52. This layout allows the p-side layer 40 and the p-side electrode 60 to oppose the second electrode 52 as explained above to facilitate the current flow between the n-side electrode 50 and the p-side electrode 60. Thus, the current density distribution nonuniformity can be further reduced.

The thickness of the first electrode 51 can be, for example, in a range of 0.1 μm to 1 μm, particularly 0.5 μm to 0.8 μm. The thickness of the first electrode 51 refers to the shortest distance between the surface of the first electrode 51 contacting the exposed region 22a and the opposing surface of the first electrode 51 that is parallel to the semiconductor structure forming face of the substrate 10, which corresponds to the distance denoted as t1 in FIG. 5. Setting the thickness of the first electrode 51 to fall within the ranges described above can facilitate the formation of the n-side pad electrode 80 while reducing the resistance of the first electrode 51.

The thickness of the second electrode 52 can be, for example, in a range of 0.5 μm to 1.5 μm, particularly 0.7 μm to 1 μm. The thickness of the second electrode 52 similarly refers to the shortest distance between the surface of the second electrode 52 contacting the exposed region 22a and the opposing surface of the second electrode 52 that is parallel to the semiconductor structure forming face of the substrate 10, which corresponds to the distance denoted as t2 in FIG. 5. Setting the thickness of the second electrode 52 to fall within the ranges described above can facilitate the formation of the n-side pad electrode 80 while reducing the resistance of the second electrode 52.

### P-Side Electrode

A p-side electrode 60 is disposed on substantially the entire upper face of the p-side layer 40. The p-side electrode 60 may be made of a metal that reflects the ultraviolet light emitted by the active layer 30 towards the n-side layer 20. For the p-side electrode 60, a metal having a reflectance of 50% or higher, preferably 60% or higher for the peak wavelength of ultraviolet light is preferably used, for example. For the p-side electrode 60, for example, a metal, such as Rh, Ru, or the like, is preferably used. The p-side electrode 60 may have a stack structure in which multiple metal layers are stacked. The p-side electrode 60 may be a stack structure in which a Ru layer, a Ni layer, and an Au layer are successively stacked from the semiconductor structure 100 side, for example. Alternatively, the p-side electrode 60 may be a stack structure in which a Ti layer, a Rh layer, and a Ti layer are successively stacked from the semiconductor structure 100 side. The thickness of the p-side electrode 60 can be set in a range of, for example, 300 nm to 1500 nm.

### Insulation Layer

The light emitting element 1 according to this embodiment has a structure in which an n-side pad electrode 80 and a p-side pad electrode 90 are disposed on the same side of the semiconductor structure 100. In this embodiment, an insulation layer 70 is used to electrically isolate the n-side electrode 50 and the p-side electrode 60 while securing the conduction between these electrodes and the n-side pad electrode 80 and the p-side pad electrode 90 such that the n-side pad electrode 80 and the p-side electrode 90 can be positioned on the right side and the left side, respectively, in FIG. 1. In FIG. 1, the insulation layer 70 covers the semiconductor structure 100, the n-side electrode 50, and the p-side electrode 60. The insulation layer 70 has a first opening 71 for exposing a portion of the surface of the n-side electrode 50 and a second opening 72 for exposing a portion of the surface of the p-side electrode 60.

For the insulation layer 70, a material selected from SiO₂, SiN, SiON and the like can be used. The thickness of the insulation layer 70 can be 1 μm to 2 μm. The insulation layer 70 may be a multilayer film composed of two or more layers.

### Pad Electrode

An n-side pad electrode 80 and a p-side pad electrode 90 are the parts that are electrically connected to an external power supply. The n-side pad electrode 80 is electrically connected to the n-side electrode 50 at the first opening 71 of the insulation layer 70 and the p-side pad electrode 90 is electrically connected to the p-side electrode 60 at the second opening 72 of the insulation layer 70.

The n-side pad electrode 80 and the p-side pad electrode 90 are indicated with solid lines in the plan view in FIG. 1. In the plan view, the area of the n-side pad electrode 80 and the area of the p-side pad electrode 90 are each 20% to 40% of the area of the light emitting element 1 in the plan view, for example.

The n-side pad electrode 80 and the p-side pad electrode 90 can each be made of a material containing at least one of those metals selected from Au, Ag, Pt, Ti, Ni, Ge, Rh, and Ru. For example, they can be made of an alloy, particularly a eutectic mixture having one or more of these metals as components. Examples of eutectic mixtures for use as the n-side pad electrode 80 and the p-side pad electrode 90 include an Au—Sn eutectic mixture and an Ag—Sn eutectic mixture. The thicknesses of the n-side pad electrode 80 and the p-side pad electrode 90 may each be 720 nm to 1080 nm.

### Embodiment 2

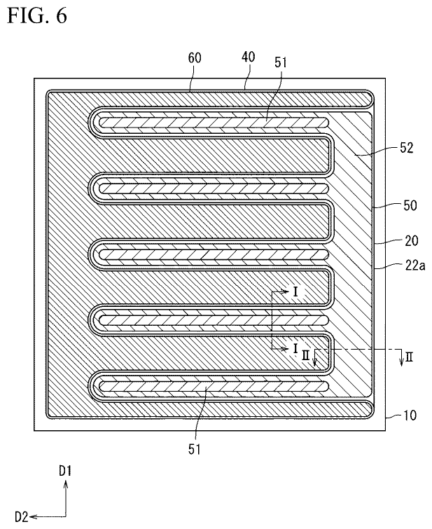

Embodiment 2 will be explained next. In the description below and FIG. 6 to FIG. 8, the members denoted by the same reference numerals as those in Embodiment 1 are the same members that have been described with reference to Embodiment 1, and the same description applies except for the parts described as different from Embodiment 1.

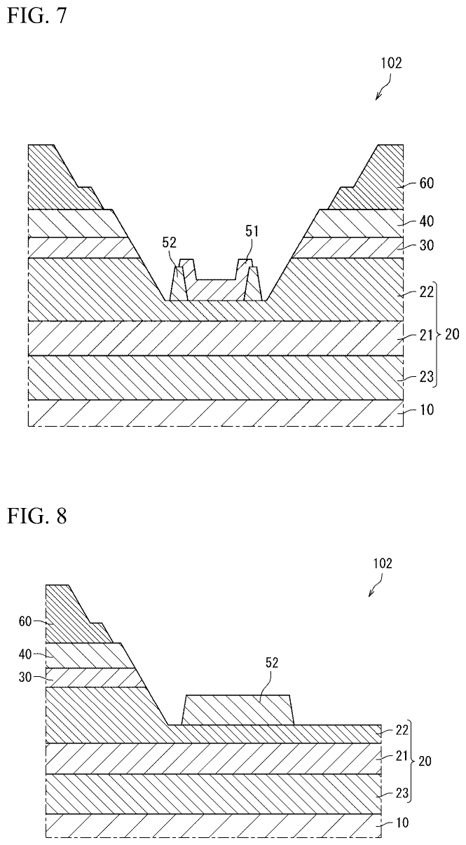

FIG. 6 shows an example in which the first electrode 51 of the n-side electrode 50 is located in each of the second regions 22a2 of the exposed region 22a of the second layer 22 shown in FIG. 3 over the entire length of the second region 22a2. In FIG. 6, only the second electrode 52 is located in the first region 22a1 shown in FIG. 3. FIG. 7 is a cross-sectional view schematically showing a portion of the light emitting element 102 taken along line I-I in FIG. 6, and FIG. 8 is a cross-sectional view schematically showing a portion of the light emitting element 102 taken along line II-II in FIG. 6.

In a plan view, each of the second regions 22a2 is interposed by the sections of the p-side layer 40, and is a part where the second electrode 52 and the p-side electrode 60 form a short current path. Accordingly, the active layer 30 in the vicinity of the second regions 22a2 tends to emit a large amount of light to increase the brightness. In this embodiment, ultraviolet light can be efficiently reflected by positioning the first electrode 51 only in the vicinity of an area where a large amount of light is emitted. Moreover, the Vf increase attributed to the layout of the first electrode 51 can be further lessened by providing only the second electrode 52 which has lower contact resistance with the second layer 22 in the first region 22al.

The first electrode 51 does not have to be located over the entire lengths of the second regions 22a2 in the second direction D2. The first electrode 51 may be located only in some of the second regions 22a2 instead of all of the second regions 22a2. For example, the first electrode 51 may be located in the second regions 22a2 that are interposed by the two second regions 22a2 positioned at both ends in the first direction D1, i.e., not located in the two second regions 22a2 positioned at both ends. Locating the first electrode 51 in this manner can increase the emission intensity in the vicinity of the center of the light emitting element 102 to facilitate light distribution control.

In this embodiment, regardless of the layout of the first electrode 51, the sum of the areas of contact between the first electrode 51 and the second regions 22a2 in a plan view is preferably set in a range of 10% to 80% of the contact area between the entire n-side electrode 50 and the second regions 22a2, and may particularly be 30% to 60%.

### Embodiment 3

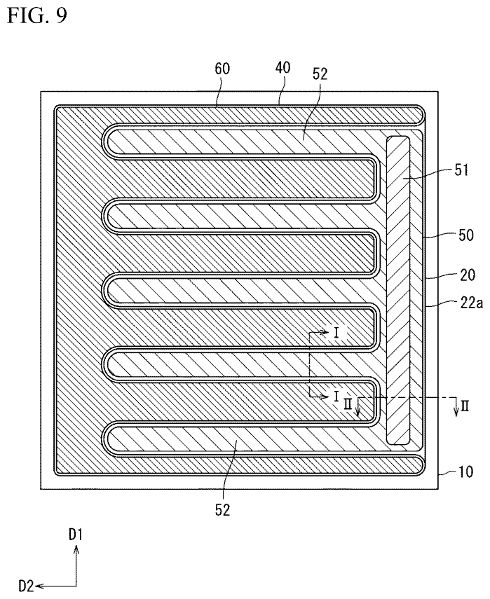

Embodiment 3 will be explained next. In the description below and FIG. 9 to FIG. 11, the members denoted by the same reference numerals as those in Embodiment 1 are the same members that have been described with reference to Embodiment 1, and the same description applies except for the parts described as different from Embodiment 1.

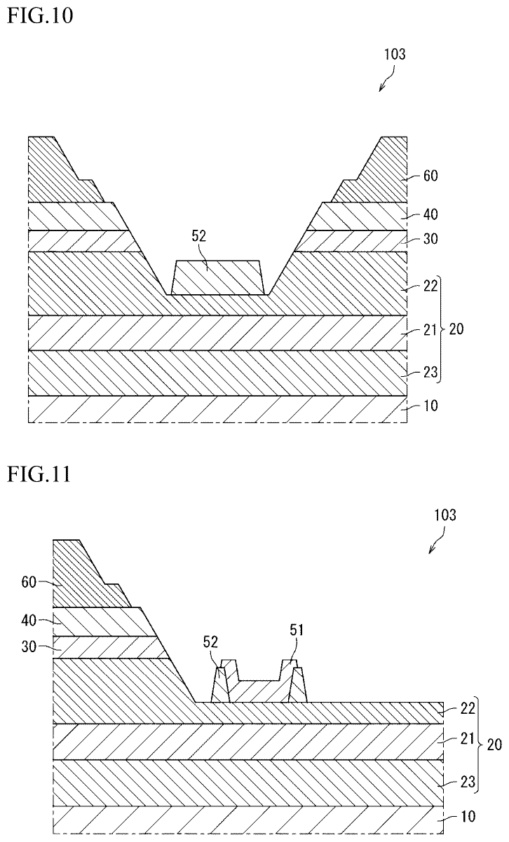

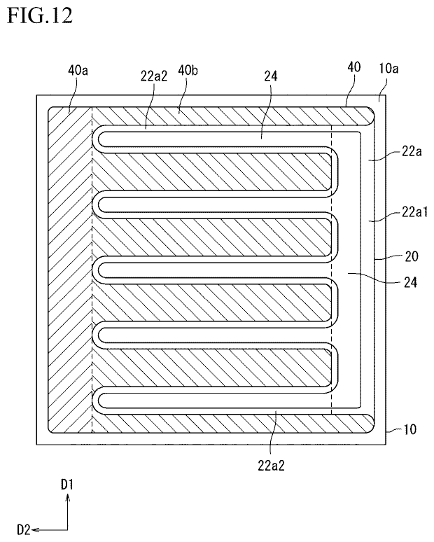

FIG. 9 shows an example in which the first electrode 51 of the n-side electrode 50 is located in the first region 22a1 of the exposed region 22a of the second layer 22 shown in FIG. 3. In FIG. 9, only the second electrode 52 is located in the second regions 22a2 shown in FIG. 3. FIG. 10 is a cross-sectional view of a portion of the light emitting element 103 taken along line I-I in FIG. 9. FIG. 11 is a cross-sectional view of a portion of the light emitting element 103 taken along line II-II in FIG. 9.

According to this layout, the ultraviolet light reflection by the first electrode 51 only occurs in the first region 22al, and the second electrode 52 has good electrical contact with the second layer 22 in the second regions 22a2. This configuration can lessen the Vf increase attributed to the placement of the first electrode 51 in the light emitting element 1 as a whole by smoothly supplying electrons from the n-side electrode 50 to the n-side layer 20 in the second region 22a2 where the current tends to concentrate, while improving the emission efficiency by reflecting ultraviolet light in the first region 22a1. According to Embodiment 3, the reliability of the light emitting element 103 can be improved. In other words, the areas near the second regions 22a2 easily generate heat because of the current concentration. Such heat generation can cause the light emitting element 103 to fail. According to this embodiment, heat generation near the second regions 22a2 can be reduced by placing the second electrode 52 which has relatively low contact resistance with the second layer 22 in the regions where electric current easily concentrates. This, as a result, can improve the reliability of the light emitting element 103.

### Embodiment 4

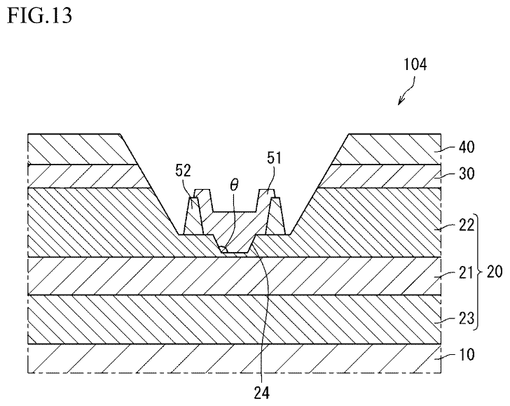

Embodiment 4 will be explained next. In the description below and FIG. 12 to FIG. 14, the members denoted by the same reference numerals as those in Embodiment 1 are the same members that have been described with reference to Embodiment, and the same description applies except for the parts described as different from Embodiment 1.

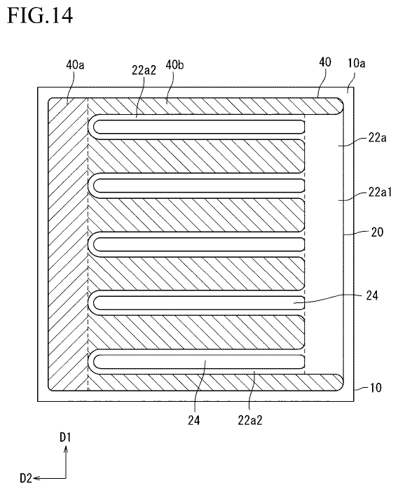

In this embodiment, the upper face of the exposed region 22a of the second layer 22 has a recess 24 which corresponds to the location of the first electrode 51, and the first electrode 51 is partly located in the recess 24. FIG. 12 shows the plan view shape of the recess 24 and FIG. 13 shows a cross section of a portion of the light emitting element 104 which is a cross section of the n-side electrode 50 where a portion of the first electrode 51 is located in the recess 24.

Positioning a portion of the first electrode 51 in the recess 24 can increase the contact area between the first electrode 51 and the second layer 22, i.e., the area that reflects the ultraviolet light emitted by the active layer 30, thereby further improving the emission efficiency.

The area of the recess 24 in a plan view can be, for example, 10% to 70%, particularly 30% to 50% of the area of the exposed region 22a in the plan view. The recess 24 may be 30 μm to 50 μm in length in the first direction D1 in the second regions 22a2, and 30 μm to 80 μm in length in the second direction D2 in the first region 22al.

The bottom face of the recess 24 does not reach the undoped first layer 21. As described above, the first layer 21 is a part having high electrical resistance that does not easily function as an electric current path. The bottom face of the recess 24 not reaching the first layer 21 allows the second layer 22 to be positioned under the recess 24. This can facilitate current diffusion. The depth of the recess 24 is preferably 0.1 μm to 5 μm, more preferably 0.5 μm to 3 μm. Setting the depth of the recess 24 in such a range can facilitate current diffusion by retaining the thickness of the second layer 22 located under the recess 24 while fully achieving the effect of increasing the emission efficiency by increasing the contact area between the first electrode 51 and the second layer 22.

As shown in FIG. 13, in the case in which the lateral faces of the recess 24 in the cross section are oblique, the angle θ formed by the bottom face and each of the lateral faces that define the recess 24 is preferably set to 100° to 140°, more preferably 110° to 130°. Setting the oblique angle in such a range can achieve good adhesion between the first electrode 51 and the second layer 22. Furthermore, the angle θ falling within such a range can further improve the emission efficiency. This is believed to be because the recess 24 plays the role of reducing the total internal reflection of the light reflected by the first electrode 51 in the semiconductor structure 100, and the angle formed by the bottom face and each lateral face that define the recess 24 falling within the ranges described above further reduces the total internal reflection.

The recess 24 may be located only in the second regions 22a2 of the second layer 22 as shown in FIG. 14. As described above, the active layer 30 in the vicinity of the second regions 22a2 tends to emit a large amount of light. The first electrode 51 located in the recesses 24 in the second regions 22a2 can efficiently reflect light. By not providing any recess 24 in the first region 22a1, the second layer 22 in the first region 22a1 can have a large thickness to lessen the Vf increase. The layout of the recesses 24 shown in FIG. 14 is preferably combined with the layout of the first electrode 51 of Embodiment 2.

In FIG. 13 and FIG. 12, the recess 24 may be located in some of the second regions 22a2. The recess 24 may be provided only in a portion of the first region 22al. For example, the recess 24 may be located in the second regions 22a2 that are interposed by the two second regions 22a2 positioned at both ends in the first direction D1, i.e., not located in the two second regions 22a2 positioned at both ends. Locating the recess 24 in this manner can increase the emission intensity near the center of the light emitting element 104 to facilitate light distribution control. In FIG. 13 and FIG. 12, the recess 24 may extend partly in length of the second regions 22a2 in the second direction D2, rather than over the entire length, for example. In FIG. 13, the recess 24 may extend partly in length of the first region 22a1 in the first direction D1, rather than over the entire length.

### Embodiment 5

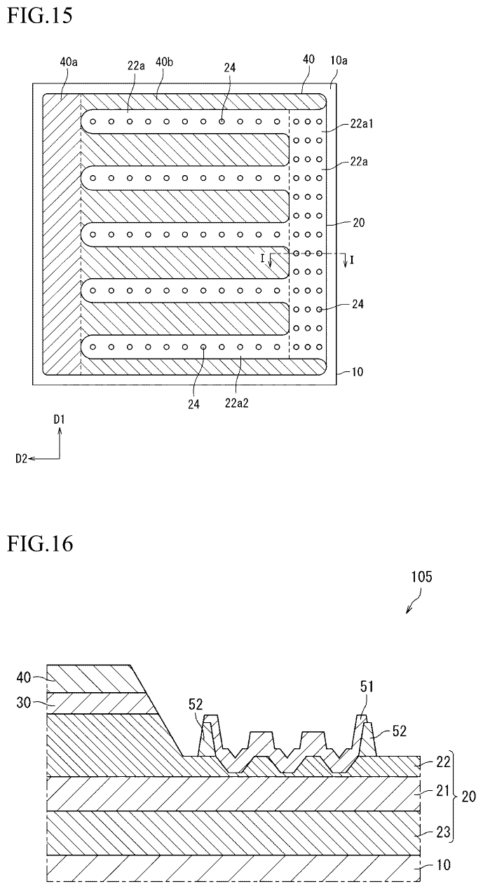

Embodiment 5 will be explained next. In the description below and FIG. 15 to FIG. 17, the members denoted by the same reference numerals as those in Embodiment 1 are the same members that have been described with reference to Embodiment 1, and the same description applies except for the parts described as different from Embodiment 1.

In this embodiment, both the first region 22a1 and the second regions 22a2 of the exposed region 22a of the second layer 22 have multiple recesses 24. FIG. 15 shows an example in which the first region 22a1 and the second regions 22a2 each have multiple circular recesses 24 in the plan view. FIG. 16 is a cross-sectional view of a portion of the light emitting element 105 showing the state in which the first electrode 51 is continuously disposed over multiple recesses 24 in a cross section taken along line I-I in FIG. 15. Similar to the recess 24 of Embodiment 4, each recess 24 is defined by a bottom face and an oblique lateral face, and its three-dimensional shape is a truncated cone. Disposing the first electrode 51 continuously to straddle multiple recesses increases the contact area between the first electrode 51 and the second layer 22. This can further increase the amount of ultraviolet light reflected, thereby further increasing the emission efficiency.

Preferable depth and the oblique angle of the lateral wall of each of the recesses 24 shown in FIG. 15 are as described with reference to Embodiment 4. In FIG. 15, the plan view shape of each recess 24 is a circle, but the plan view shape of the recess 24 is not limited to this. The shape may be an ellipse, a polygon, such as a triangle, quadrangle, or the like.

In a plan view, the area of each recess 24 in the exposed region 22a is, for example, 50000 μm² to 200000 μm², particularly 100000 μm² to 150000 μm². The recess 24 density, i.e., the percentage of the recesses 24 occupying the exposed region 22a, can be, for example 10% to 50%, particularly 30% to 40%. If the density of the recesses 24 is too low, the recesses 24 might become too spaced apart to adequately achieve the effect of providing multiple recesses 24. If the density of the recesses 24 is too high, it might be difficult to form the recesses 24 in the exposed regions 22. If the area per recess 24 is small, the effect of forming the recesses 24 might not be achieved fully. If the area per recess 24 is large, the number of recesses across which the first electrode 51 can be continuously formed would be reduced to achieve the effect of providing multiple recesses 24.

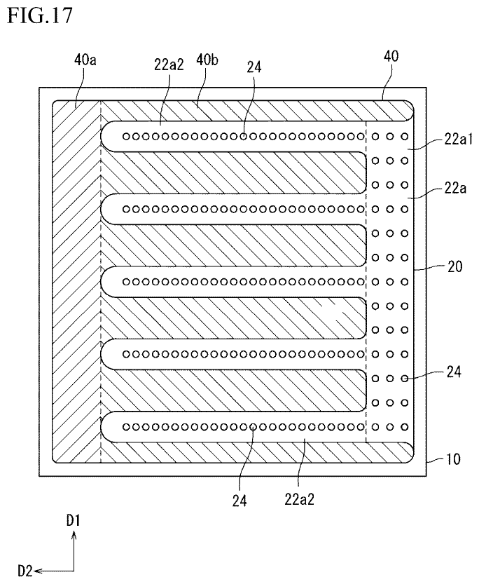

As shown in FIG. 17, the density of the recesses 24 provided in the second regions 22a2 may be set higher than the density of the recesses 24 provided in the first region 22al. The second regions 22a2 oppose the sections of the p-side layer 40 over the entire length in the second direction D2, and are close to the active layer 30. Accordingly, providing high density recesses 24 in the second regions 22a2 and disposing the first electrode 51 continuously across multiple recesses 24 can further increase the ultraviolet light reflection by the first electrode 51 to thereby further improve the emission efficiency. The recesses 24 may be provided to have a density difference such that the percentage of the recesses 24 in the surfaces of the second regions 22a2 is set, for example, in a range of 20% to 70%, particularly 40% to 60%, and the percentage of the recesses 24 in the surface of the first region 22a1 is set in a range of 20% to 70%, particularly 40% to 60%.

The layout of the recesses 24 shown in FIG. 17 is preferably combined with the layout of the first electrode 51 of Embodiment 2.

Furthermore, in the case of employing the first electrode layout of Embodiment 3, the density of the recesses 24 in the first region 22a1 may be set higher than the density of the recesses 24 in the second regions 22a2.

### Embodiment 6

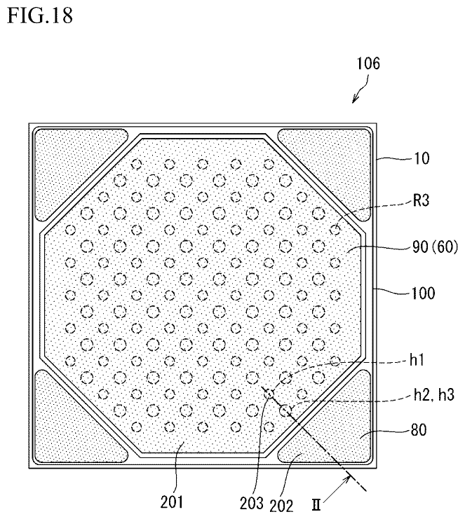

Embodiment 6 will be explained next. In the description below and FIG. 18 to FIG. 21, the members denoted by the same reference numerals as those in Embodiment 1 are the same members that have been described with reference to Embodiment 1, and the same description applies except for the parts described as different from Embodiment 1.

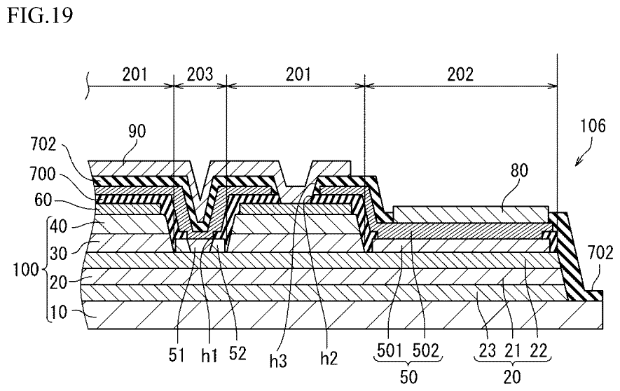

FIG. 18 is a plan view of a light emitting element 106 according to this embodiment, and FIG. 19 is a cross-sectional view taken along line II in FIG. 18. In this embodiment, the n-side layer 20 has a first portion 201, a second portion 202 that is located on the periphery of the first portion 201, and multiple third portions 203 surrounded by the first portion. The active layer 30 and the p-side layer 40 are disposed on the first portion 201. A first insulation film 700 is disposed on the semiconductor structure 100, and the first insulation film 700 has multiple first holes h1 located on the third portions 203 and multiple second holes h2 located on the p-side layer 40. The n-side electrode 50 is disposed on the first insulation film 700, and the first insulation film 700 electrically isolates the n-side electrode 50 and the p-side electrode 60. The n-side electrode 50 is electrically connected to the n-side layer 20 in the first openings h1. The n-side electrode 50 is electrically connected to the n-side pad electrode 80 disposed on the second portion 202. The n-side pad electrode 80 has a shape that corresponds to the second portion 202 in a plan view.

The second openings h2 located on the p-side layer 40 expose the p-side electrode 60 that is electrically connected to the p-side layer 40. On the first insulation film 700, a second insulation film 702 is disposed, and the second insulation film 702 has multiple third openings h3 positioned to overlap the second openings h2. The p-side electrode 60 is electrically connected to the p-side pad electrode 90 that is disposed on the second insulation film 702 at the second holes h2 and the third holes h3. The second insulation film 702 electrically isolates the n-side electrode 50 and the p-side pad electrode 90, and electrically isolates the n-side pad electrode 80 and the p-side pad electrode 90. The p-side pad electrode 90 has an octagonal plan view shape which corresponds to the first portion 201 and is provided over a relatively large area to contribute to improving heat dissipation.

The layering configuration of the n-side layer 20, which is the same as that in Embodiment 1, includes a third layer 23 as a superlattice layer, an undoped first layer 21 as an under layer, and a second layer 22 containing an n-type impurity as a contact layer. The second portion 202 and the third portions 203 correspond to the portions of the n-side layer 20 that are exposed from the p-side layer 40 and the active layer 30 where the second layer 22 containing an n-type impurity is exposed.

The n-side electrode 50 has an n-side conducting part 501 and an n-side wiring part 502. The n-side conducting part 501 is electrically connected to the n-side layer 20 in the first openings h1, and the n-side wiring part 502 electrically connects the n-side conducting part 501 and the n-side pad electrode 80. The n-side conducting parts 501a located in the first openings h1 each include a first electrode 51 and a second electrode 52. The first electrode 51 and the second electrode 52 are in contact with the second layer 22, but not in contact with the first layer 21. In a plan view, the first electrode 51 at each location is circular and the second electrode 52 surrounds the first electrode 51. In a cross-sectional view, the lateral face of the first electrode 51 is in contact with the second electrode 52.

The first electrode 51 and the second electrode 52 of the n-side electrode 50 may be located on the second portion 202 instead of, or in addition to, the first portion 201.

Instead of separately forming the n-side conducting part 501 and the n-side wiring part 502, for example, the first electrode 51 may be formed in the positions that correspond to the first openings h1, followed by forming the first insulation film 700, and integrally forming the second electrode 52 and the n-side wiring part 503 using the same material. In this case, the second electrode 53 and the n-side wiring part 502 are integrated. Thus, there would be no border line between the n-side conducting part 501 and the n-side wiring part 502 like the one that is shown in FIG. 19.

A third portion 203 where a first opening h1 is located is surrounded by the p-side layer 40 and the active layer 30 which shortens the electric current path between the n-side electrode 50 and the p-side electrode 60. Thus, the area in the vicinity of a third portion 203 tends to have high brightness, i.e., a larger amount of light is emitted. Accordingly, positioning the first electrode 51 having a high reflectance in the third portions 203 can efficiently reflect ultraviolet light in the areas where the emitted ultraviolet light concentrate, thereby improving the emission efficiency.

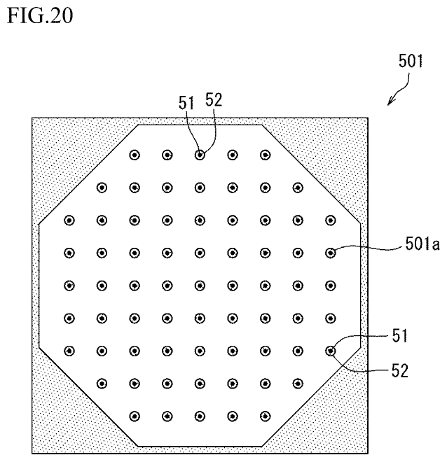

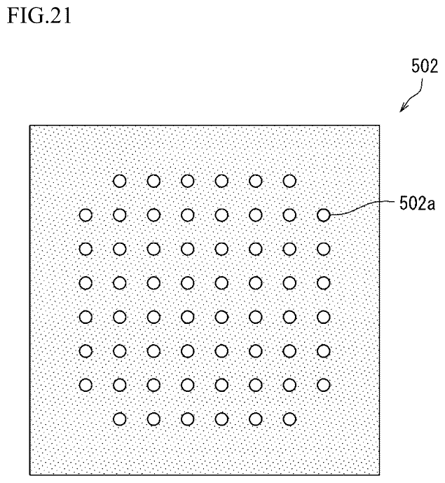

FIG. 20 and FIG. 21 are plan views of the n-side conducting parts 501 and the n-side wiring part 502 of the n-side electrode 50, respectively. The n-side conducting parts 501 are positioned substantially at equal intervals, and can diffuse the electric current to thereby improve the emission intensity distribution uniformity. The openings 502a of the n-side wiring part 502 correspond to the second openings h2 and the third openings h3 of the first insulation film 700 and the second insulation film 702, exposing the p-side electrode 60 together with the second openings h2 and the third openings h3 so as to electrically connect the p-side pad electrode 90 and the p-side electrode 60.

### EXAMPLES

### Examples 1 to 6

Light emitting elements 1 having the structure shown in FIG. 1 and FIG. 2 provided with the recess 24 shown in FIG. 12 and FIG. 13 on the surface of the second layer 22 were produced as Examples 1 to 6. Specifically, in each case, the substrate 10 had a square shape, 1 mm per side, in a plan view. The n-side layer 20 had a third layer 23 made up of 30 pairs of alternately stacked AlN layers and AlGaN layers having an Al composition ratio of 60% as a superlattice layer (945 nm in thickness), a first layer 21 made of an undoped AlGaN layer having an Al composition ratio of 60% as an underlayer (480 nm in thickness), and a second layer 22 as an n-contact layer having an Al composition ratio of 60% and containing about 9.5×10¹⁸/cm³ concentration Si as an n-type impurity (2220 nm in thickness). The active layer 30 had a multiple quantum well structure in which each well layer was an AlGaN layer having an Al composition ratio of 42% (4.4 nm in thickness) and each barrier layer was AlGaN layer having an Al composition ratio was 52% (2.5 nm in thickness). The total thickness of the active layer 30 was 11.3 nm. The p-side layer 40 was a multilayer structure in which a 10 nm-thick GaN layer was disposed on a 10 nm-thick AlGaN layer having an Al composition ratio of 40% and containing 1×10¹⁹/cm³ concentration Mg as a p-type impurity.

Etching was performed on the semiconductor structure 100 having up to the p-side layer 40, the p-side layer 40 and the active layer 30 were removed, and the n-side layer 20 was exposed. The exposed region 22a had a first region 22a1 where the n-side layer 20 extended in the first direction D1, and second regions 22a2 orthogonal to the first direction D1 and extending from the first region 22a1 as shown in FIG. 3. The exposed region 22a was 450934 μm² in area in a plan view. The length (width) of the first region 22a1 in the second direction D2 and the length in the first direction D1 were 106 μm and 814 μm, respectively. The length (width) of each second region 22a2 in the first direction D1 and the length in the second direction D2 were 62 μm and 794 μm, respectively. Five second regions 22a2 were located at 126-μm intervals along the first direction D1.

On the surface of the exposed region 22a, a recess 24 having the plan view shape shown in FIG. 12 was created. The width of the recess 24 located in each second region 22a2 in the first direction D1 was 20 μm, and the width of the recess 24 located in the first region 22a1 in the second direction D2 was 60 μm. The area of the recess 24 in a plan view was 123144 μm². In Examples 1 to 6, the configuration of the recess was varied by using the combinations of the depth of the recess 24 and the oblique angle of the recess 24 shown in Table 1.

TABLE 1

| | Depth of Recess (μm) | Oblique Angle of Recess (μm) |
|---|---|---|
| Example 1 | 1 | 113 |
| Example 2 | 1 | 124 |
| Example 3 | 1 | 130 |
| Example 4 | 2 | 113 |
| Example 5 | 2 | 124 |
| Example 6 | 2 | 130 |

A second electrode 52 having the cross-sectional shape shown in FIG. 5 was formed by stacking a Ti—Al—Si alloy layer, a Ta layer, and an Ru layer on the first region 22a1 and the second regions 22a2 in that order, and partially removing them by etching. A p-side electrode 60 was formed by stacking a Ti layer, an Rh layer, and a Ti layer on the upper face of the p-side layer 40 in that order. After forming the second electrode 52 and the p-side electrode 60, the semiconductor structure and these electrodes were annealed. Subsequent to the annealing process, a first electrode 51 was formed by stacking an Al—Cu alloy layer, a Ti layer, and an Ru layer in that order. The second electrode 52 first electrode 51 was disposed in the recess formed by the second electrode 52 such that a portion thereof extended onto the upper face of the second electrode 52 as shown in FIG. 5. The n-side electrode 50 made up of the first electrode 51 and the second electrode 52 was 248732 μm² in area in a plan view.

An insulation layer 70 was formed to have a first opening 71 that exposed a portion of the surface of the n-side electrode 50 and a second opening 72 that exposed a portion of the surface of the p-side electrode 60. The first opening 71 and the second opening 72 were formed by dry etching. The insulation film 70 was made of SiO₂ and 1.3 μm in thickness.

An n-side pad electrode 80 and a p-side pad electrode 90 were formed to have the plan view shapes shown in FIG. 1. The n-side pad electrode 80 and the p-side pad electrode 90 were each made up of Ti, Pt, and Au layers, and 900 nm in thickness.

### Comparative Example

A comparative example having similar shape and configuration to those of the examples described above except for not including a recess 24 and composing the n-side electrode 50 only with a second electrode 52, i.e., no first electrode 51, was prepared.

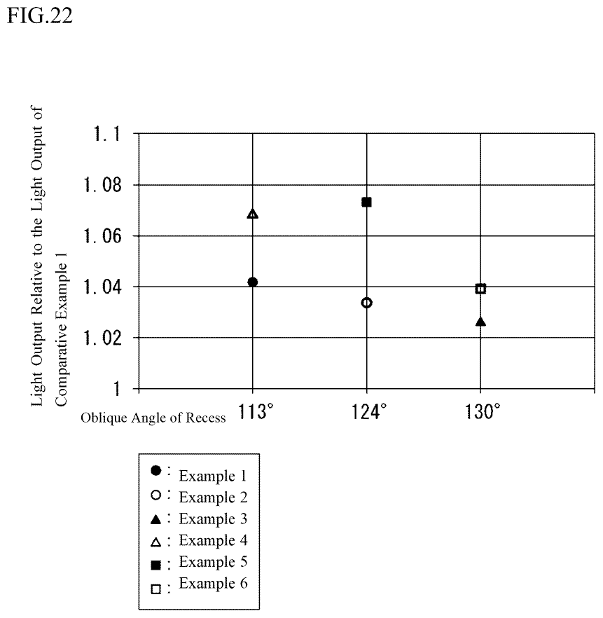

The light outputs of Examples 1 to 6 and the Comparative Example were measured by applying a 350 mA current. The light output of each of the Examples 1 to 6 was compared with the light output of the Comparative Example to obtain the rate. FIG. 22 shows the results.

All of the Examples showed a higher light output than that of the Comparative example, which confirmed that the first electrode 51 improves the emission efficiency of the light emitting elements 1.

A light emitting element according to the present disclosure can be used as one that emits ultraviolet light efficiently, for example, in a resin curing light source, a lamp for sterilization and disinfection, an industrial exposure apparatus, or the like.

1. A light emitting element comprising:
a semiconductor structure that comprises an n-side layer, a p-side layer, and an ultraviolet light emitting active layer positioned between the n-side layer and the p-side layer, each being made of a nitride semiconductor;
an n-side electrode electrically connected to the n-side layer; and
a p-side electrode electrically connected to the p-side layer; wherein:
the n-side layer comprises an undoped first layer, and a second layer positioned between the active layer and the first layer and containing an n-type impurity;
the n-side electrode comprises a first electrode and a second electrode that are in contact with the second layer, but not in contact with the first layer;
a reflectance of the first electrode for a peak wavelength of light emitted from the active layer is higher than a reflectance of the second electrode for the peak wavelength of the light emitted from the active layer; and
a contact resistance between the second electrode and the second layer is lower than a contact resistance between the first electrode and the second layer.

2. The light emitting element according to claim 1, wherein:
the second layer has an exposed region exposed from the p-side layer and the active layer;
the exposed region has a first region extending in a first direction, and a second region extending in a second direction that is orthogonal to the first direction and positioned between sections of the p-side layer in the first direction;
the n-side electrode is disposed continuously over the first region and the second region;
the first electrode and the second electrode are disposed in the second region; and
the second electrode, but not the first electrode, is disposed in the first region.

3. The light emitting element according to claim 1, wherein:
the second layer has an exposed region exposed from the p-side layer and the active layer;
the exposed region has a first region extending in a first direction, and a second region extending in a second direction that is orthogonal to the first direction and positioned between sections of the p-side layer in the first direction;
the n-side electrode is disposed continuously over the first region and the second region;
the first electrode and the second electrode are disposed in the first region; and
only the second electrode is disposed in the second region.

4. The light emitting element according to claim 1, wherein a portion of the first electrode is positioned between sections of the second electrode in a cross section, and at least a portion of each of the two lateral faces of the first electrode is in contact with the second electrode.

5. The light emitting element according to claim 1, wherein:
the second layer has a recess; and
a portion of the first electrode is located in the recess.

6. The light emitting element according to claim 2, wherein:
the second layer has a recess; and
a portion of the first electrode is located in the recess.

7. The light emitting element according to claim 3, wherein:
the second layer has a recess; and
a portion of the first electrode is located in the recess.

8. The light emitting element according to claim 5, wherein:
the second layer has a plurality of recesses; and
the first electrode is disposed continuously over the recesses.

9. The light emitting element according to claim 6, wherein:
the second layer has a plurality of recesses; and
the first electrode is disposed continuously over the recesses.

10. The light emitting element according to claim 7, wherein:
the second layer has a plurality of recesses; and
the first electrode is disposed continuously over the recesses.

11. The light emitting element according to claim 6, wherein:
the recesses are located in the first region and the second region; and
a density of the recesses in the second region is higher than a density of the recesses in the first region.

12. The light emitting element according to claim 11 wherein a depth of the recesses is 0.1 μm to 5 μm.

13. The light emitting element according to claim 11 wherein an angle formed by the bottom face and the lateral face that define each recesses is 100° to 140°.

14. The light emitting element according to claim 1, wherein, in a plan view, an outline of the second electrode surrounds an outline of the first electrode.

15. The light emitting element according to claim 2, wherein, in a plan view, an outline of the second electrode surrounds an outline of the first electrode.

16. The light emitting element according to claim 3, wherein, in a plan view, an outline of the second electrode surrounds an outline of the first electrode.

17. The light emitting element according to claim 1, wherein:
the n-side layer has a first portion, a second portion positioned proximate a periphery of the first portion, and a third portion surrounded by the first portion in a plan view;
the active layer and the p-side layer are disposed on the first portion;
a first insulation film is disposed on the semiconductor structure, the first insulation film having a plurality of first openings located on the third portion and a plurality of second openings located on the p-side layer and exposing the p-side electrode;
the n-side electrode is disposed on the first insulation film and electrically connected to the n-side layer at the first openings;
an n-side pad electrode electrically connected to the n-side electrode is disposed in the second portion; and
the first electrode and the second electrode are located in one or more of the first openings.

18. The light emitting element according to claim 17, wherein:
the n-side electrode comprises a plurality of n-side conducting parts and an n-side wiring part;
the n-side conducting parts are in contact with the n-side layer at the first openings;
the n-side wiring part electrically connects the n-side conducting parts and the n-side pad electrode; and
one or more of said plurality of n-side conducting parts are made up of the first electrode and the second electrode.
